(19) United States
(12) Patent Application Publication
(10) Pub. No.: US 2002/0145146 A1
(43) Pub. Date: Oct. 10, 2002

(54) LED of AlGaInP system and epitaxial wafer used for same

(76) Inventors: Kenji Shibata, Ibaraki-ken (JP); Masatomo Shibata, Ibaraki-ken (JP); Taichiro Konno, Ibaraki-ken (JP); Naoki Kaneda, Ibaraki-ken (JP); Masahiro Noguchi, Ibaraki-ken (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/558,588

(22) Filed: Apr. 26, 2000

(30) Foreign Application Priority Data
Apr. 27, 1999 (JP) 11-120121
Jun. 25, 1999 (JP) 11-180539

(51) Int. Cl. H01L 31/12; H01L 33/00; H01L 27/15

(52) U.S. Cl. 257/79

(57) ABSTRACT

A high potential barrier is prevented from being formed on a hetero-boundary surface between a p-type AlGaInP cladding layer and a p-type GaP window layer by forming an insertion layer having a smaller band gap energy than that of the p-type AlGaInP cladding layer therebetween. The insertion layer serves as a forward voltage reducing layer, and the forward voltage of a LED is lowered.

### FIELD OF THE INVENTION

The invention relates to a light emitting diode of an AlGaInP system for emitting a light having a wavelength of 650 nm (red) to 550 nm (yellow-green region), and an epitaxial wafer used for the same.

### BACKGROUND OF THE INVENTION

Recently, the light emitting diode (LED, hereinafter) of an AlGaInP system for emitting a red or yellow light with high brightness are in great demand. The aforementioned diode is used for various purposes such as a traffic-control signal, a tail or fog lamp of an automobile, and a full color display.

FIG. 1 shows a structure of a conventional epitaxial wafer for the LED of AlGaInP system for emitting a light having a wavelength of 590 nm.

The epitaxial wafer for the LED shown in FIG. 1 is fabricated by successively growing a n-type GaAs buffer layer 2a, a n-type (Al_{0.7}Ga_{0.3})_{0.5}In_{0.5} P cladding layer 3a, an undoped (Al_{0.7}Ga_{0.9})_{0.5}In_{0.5} P active layer 4a, a p-type (Al_{0.7}Ga_{0.3})_{0.5}In_{0.5} P cladding layer 5a, and a p-type GaP window layer 6a on a n-type GaAs substrate 1a.

All the epitaxial layers 2a to 6a are grown by the metal organic vapor phase epitaxial growth (MOVPE, hereinafter) method. Although an AlGaAs layer in which a composition ratio of Al is more than 0.6 is sometimes used as the window layer of the LED, this window layer is not suited for effectively transmitting the light to be emitted, and apt to be deteriorated. From this point of view, the GaP layer is suited for the window layer because of a large band gap and an oxidation-resisting property thereof.

However, there are following problems on the GaP window layer.

FIG. 2 explains structures of energy bands near the hetero-boundary surface between the p-type window layer 6a and a p-type AlGaInP cladding layer 5a in the epitaxial layers of the LED of AlGaInP system. Herein, an arrow in FIG. 2 shows a direction of movement of positive hole in case that a forward voltage is applied thereto.

In the p-type GaP window layer 6a and the p-type (Al_{0.7}Ga_{0.3})_{0.5}In_{0.5}P cladding layer 5a, a high potential barrier (a discontinuity in the energy bands) is formed on the hetero-boundary surface because of a difference in an affinity for electrons between the p-type cladding layer 5a and the window layer 6a, wherein the potential barrier shown in a broken line circle B obstructs the movement of the positive holes. When the LED is activated, the potential barrier becomes a primary factor for obstructing the movements of the positive holes from the p-type window layer 6a to the p-type (Al_{0.7}Ga_{0.3})_{0.5}In_{0.5}P cladding layer 5a. As a result, the forward voltage of the LED (an operating voltage, that is to say a voltage applied to the LED in case that a current of 20 mA is supplied thereto) becomes high. In general, a reliability of the LED is lowered as the forward voltage of the LED is heightened. In the LED using the p-type GaP window layer 6a, it is an important subject to reduce the forward voltage.

FIG. 3 shows another conventional epitaxial wafer for a LED of AlGaInP system.

A wavelength of a light emitted from a LED fabricated from the epitaxial wafer shown in FIG. 3 is 590 nm. This epitaxial wafer is fabricated by successively growing a n-type GaAs buffer layer 2b, a Si or Se doped n-type AlGaInP cladding layer 3b, an undoped AlGaInP active layer 4b, a Zn-doped p-type AlGaInP cladding layer 5b, and a Zn-doped p-type GaP window layer 6b on a n-type GaAs substrate by the MOVPE growth.

As a problem related to the conventional technology, a phenomenon that Zn used as p-type dopant abnormally diffuses to a hetero-boundary surface of adjacent layers should be cited.

(1) Since the window layer 6b is in need of p-type carriers of a high concentration (about 5×10¹⁸ cm⁻³) in order to spread a current supplied from an electrode in the direction of a surface of a chip, the window layer 6b is doped with Zn of high it concentration.

(2) Since the window layer 6b is grown till it is more than 0.5 μm thick in order to promote the aforementioned spread of the current, the growth time thereof becomes long.

(3) The epitaxial wafer for the LED of AlGaInP system is generally grown at a growth temperature higher than 650° C. in order to reduce the concentration of oxygen acting as impurities.

Because of the three factors mentioned in the above, Zn is easily diffused into the epitaxial wafer driven by heat applied thereto while the epitaxial wafer is grown. Zn starts from the window layer doped with Zn of high concentration, and diffuses into the active layer serving as a light-emitting region via the p-type AlGaInP cladding layer. It is well known that, if Zn diffuses into the active layer, Zn forms non-emissive recombination centers, which deteriorates the light-emitting characteristic of the LED.

It is well known that the effect of the non-emissive recombination centers becomes noticeable when a driving current is continuously supplied to the LED, which greatly deteriorates the reliability of the LED.

### SUMMARY OF THE INVENTION

Accordingly, it is an object of the invention to prevent a high potential barrier from being formed between a p-type cladding layer and a window layer, and provide a LED of AlGaInP system in which a forward voltage is low.

It is a further object of the invention to prevent a high potential barrier from being formed between a p-type cladding layer and a window layer, and provide an epitaxial wafer for a LED of AlGaInP system in which a forward voltage is low.

It is a still further object of the invention to prevent impurities from being diffused into an active layer, and provide a LED of AlGaInP system having a high light-emitting characteristic and high reliability.

It is a yet further object of the invention to prevent impurities from being diffused into an active layer, and provide an epitaxial wafer for a LED of a AlGaInP system having a high light-emitting characteristic and high reliability.

According to the first feature of the invention, a LED of AlGaInP system comprises:

a substrate having conductivity,

a n-type cladding layer formed of compound semiconductor of AlGaInP system,

an active layer formed of compound semiconductor of AlGaInP system having a smaller band gap energy than that of the n-type cladding layer,

a p-type cladding layer formed of compound semiconductor of AlGaInP system having a larger band gap energy than that of the active layer,

a p-type window layer formed of GaP,

electrodes formed on predetermined portions of the window layer and said substrate, and

an insertion layer which is inserted between the p-type cladding layer and the p-type window layer and has a smaller band gap energy than that of the p-type cladding layer.

In addition to the aforementioned structure, if is desirable that the band gap energy of the insertion layer is larger than that of the active layer in the LED of AlGaInP system according to the invention.

In addition to the aforementioned structure, it is desirable that a conductivity type of the insertion layer in the LED according to the invention is a p-type.

In addition to the aforementioned structure, a carrier concentration of the p-type insertion layer of the LED according to the invention is 5×10¹⁷cm⁻³ to 5×10¹⁸cm⁻³.

In addition to the aforementioned structure, it is desirable that the insertion layer of the LED according to the invention is formed of material which is lattice-matched with the p-type cladding layer.

In addition to the aforementioned structure, it is desirable that the insertion layer of the LED according to the invention is formed of AlGaInP, GaInP, AlInP, GaAs, AlGaAs, GaAsP, or InGaAsP, which has such a composition that the band gap energy thereof is smaller than that of the p-type cladding layer.

In addition to the aforementioned structure, a window layer formed of GaₓIn₁₋ₓP(0<x≦1), Al_{y}In_{1-y}P(0<y≦1) or Al_{z}Ga_{1-z}P(0<z≦1) may be adopted instead of the p-type window layer formed of GaP in the LED according to the invention.

According to the second feature of the invention, an epitaxial wafer for a LED of AlGaInP system comprises:

a substrate having conductivity,

a n-type cladding layer formed of compound semiconductor of AlGaInP system,

an active layer formed of compound semiconductor of AlGaInP system having a smaller band gap energy than that of the n-type cladding layer,

a p-type cladding layer formed of compound semiconductor of AlGaInP system having a larger band gap energy than that of the active layer,

a p-type window layer formed of GaP, and

an insertion layer which is inserted between the p-type cladding layer and the p-type window layer and has a smaller band gap energy than that of the p-type cladding layer.

In addition to the aforementioned structure, it is desirable that the band gap energy of the insertion layer is larger than that of the active layer in the epitaxial wafer for the LED of AlGaInP system.

In addition to the aforementioned structure, it is desirable that a conductivity type of the insertion layer of the epitaxial wafer for the LED of AlGaInP system according to the invention is p-type.

In addition to the aforementioned structure, it is desirable that concentration of carriers of the insertion layer of the epitaxial wafer for the LED of AlGaInP system according to the invention is 5×10¹⁷cm⁻³ to 5×10¹⁸ cm⁻³.

In addition to the aforementioned structure, it is desirable that the insertion layer of the epitaxial wafer for the LED of AlGaInP system according to the invention is lattice-matched with the p-type cladding layer.

In addition to the aforementioned structure, it is desirable that the insertion layer of the epitaxial wafer for the LED of AlGaInP system according to the invention is composed of AlGaInP, GaInP, AlInP, GaAs, AlGaAs, GaAsP or InGaAsP, which has such a composition that a band gap energy thereof is smaller than that of the p-type cladding layer.

In addition to the aforementioned structure, a window layer formed of GaₓIn₁₋ₓP(0<x≦1), Al_{y}In_{1-y}P(0<y≦1) or Al_{z}Ga_{1-z}P(0<z≦1) may be adopted instead of the p-type window layer formed of GaP in the epitaxial wafer for the LED of AlGaInP system according to the invention.

According to the invention, a high potential barrier is prevented from being formed on a hetero-boundary surface between the p-type AlGaInP cladding layer and the p-type GaP layer by inserting the insertion layer having a smaller band gap energy than that of the p-type AlGaInP cladding layer between the p-type AlGaInP cladding layer and the p-type GaP window layer, so that the forward voltage of the LED is lowered.

According to the third feature of the invention, a LED of AlGaInP system comprises:

a substrate having n-type conductivity,

a n-type cladding layer formed of compound semiconductor of AlGaInP system,

an active layer formed of compound semiconductor of AlGaInP system having a smaller band gap energy than that of the n-type cladding layer,

a p-type cladding layer formed of compound semiconductor of AlGaInP system having a larger band gap energy than that of the active layer,

a p-type window layer, and

an insertion layer formed of compound semiconductor of AlGaInP system which is inserted into the p-type cladding layer or between the p-type cladding layer and the p-type window layer,

wherein the insertion layer is lattice-matched with the p-type cladding layer, and a composition ratio of Al in the insertion layer is lower than that in the p-type cladding layer and higher than that in the active layer.

In addition to the aforementioned structure, it is desirable that the LED of AlGaInP system according to the invention is provided with the window layer formed of GaP.

In addition to the aforementioned structure, it is desirable that the LED of AlGaInP system according to the invention is provided with the p-type cladding layer and the p-type window layer which are doped with Zn.

In addition to the aforementioned structure, it is desirable that concentration of carries of the insertion layer of the LED of AlGaInP system according to the invention is 2×10¹⁷cm⁻³ to 5×10¹⁸cm⁻³.

According to the fourth feature of the invention, an epitaxial wafer for a LED of AlGaInP system comprises:

a substrate having n-type conductivity,

a n-type cladding layer formed of compound semiconductor of AlGaInP system,

an active layer formed of compound semiconductor of AlGaInP system having a smaller band gap energy than that of the n-type cladding layer,

a p-type cladding layer formed of compound semiconductor of AlGaInP system having a larger band gap energy than that of the active layer,

a p-type window layer, and

an insertion layer formed of compound semiconductor of AlGaInP system which is inserted into the p-type cladding layer or between the p-type cladding layer and the p-type window layer,

wherein the insertion layer is lattice-matched with the p-type cladding layer, and a composition ratio of Al in the insertion layer is lower than that in the p-type cladding layer and higher than that in the active layer.

In addition to the aforementioned structure, it is desirable that an epitaxial wafer for a LED of AlGaInP system according to the invention is provided with a p-type window layer formed of GaP.

In addition to the aforementioned structure, it is desirable that an epitaxial wafer for a LED of AlGaInP system according to the invention comprises the p-type cladding layer and the p-type window layer which are doped with Zn.

In addition to the aforementioned structure, concentration of carriers of the insertion layer of an epitaxial wafer for the LED of AlGaInP system according to the invention is 2×10¹⁷cm³ to 5×10¹⁸cm³.

In the invention, a n-type cladding layer formed of compound semiconductor of AlGaInP system, an active layer formed of compound semiconductor of AlGaInP system having a smaller band gap energy than that of the n-type cladding layer, a p-type cladding layer formed of compound semiconductor of AlGaInP system having the larger band gap energy than that of the active layer, and a p-type window layer are successively grown on a substrate having n-type conductivity, wherein an insertion layer formed of compound semiconductor of AlGaInP system which is inserted into the p-type cladding layer or between the p-type cladding layer and the p-type window layer. Moreover, the insertion layer is lattice-matched with the p-type cladding layer, and a composition ratio of Al in the insertion layer is lower than that in the p-type cladding layer and higher than that in the active layer. According to the aforementioned structure, the output of the LED is prevented from being lowered by preventing impurities from diffusing into the active layer.

Herein, in the fabrication process of the LED of AlGaInP system, although the compositions of respective epitaxial layers are usually selected so that the lattice constant of the p-type cladding layer is matched with that of the substrate from an epitaxial layer just above the substrate to the p-type cladding layer, only a GaP layer which is not lattice-matched with the substrate must be grown on the p-type cladding layer as the window layer from viewpoints of a band gap energy, a resistivity and reliability thereof.

Accordingly, a proposal that an insertion layer having an intermediate lattice constant between those of the p-type cladding layer and the window layer is inserted therebetween in order to relax distortions in the lattices has been made on Japanese Patent Application Laid-Open No. 10-256598. Although the intention of the aforementioned proposal is to improve the crystallization of the GaP layer which is grown in condition that the lattice constant is mismatched, Zn cannot be effectively prevented from being diffused by this approach.

As the result of their enthusiastic investigations, the inventors have discovered a fact that the aforementioned diffusion of Zn is caused by defects of the crystal related to Al, and Zn is apt to diffuse in material in which a composition ratio of Al is high. On the contrary, in material in which a composition ratio of Al is low, Zn is hard to diffuse. Then, the inventors have presumed that, since it is undesirable that Zn in the p-type cladding layer and the window layer diffuses into the undoped active layer, if an insertion layer of AlGaInP system in which a composition ratio of Al is lower than that in the p-type cladding layer of AlGaInP system is inserted into the p-type cladding layer or between the p-type cladding layer and the window layer, the insertion layer serves as a resistor against the diffusion of Zn, and pollution in the active layer caused by Zn is greatly reduced as compared with the conventional LED. Moreover, it is necessary that a composition ratio of Al in the insertion layer formed of compound semiconductor of AlGaInP system is higher than that in the active layer in order to make a light emitted from the active layer transmit through the insertion layer. It is a matter of course that the insertion layer should be lattice-matched with the p-type cladding layer.

That is to say, according to the invention, a high light-emitting power and a high reliability can be obtained in case that a standard LED of AlGaInP system in which the upper electrode is used as a p-type electrode is fabricated by inserting the insertion layer in which a composition ratio of Al is lower than that in the p-type cladding layer and higher than that in the active layer into the p-type cladding layer or between the p-type window layer and the p-type cladding layer to prevent impurities from diffusing into the active layer.

### BRIEF DESCRIPTION OF THE DRAWINGS

The invention will be explained in more detail in conjunction with the appended drawings, wherein:

FIG. 1 shows a structure of a conventional epitaxial wafer for a LED of AlGaInP system for emitting a light having a wavelength of 590 nm;

FIG. 2 shows structures of energy bands in the vicinity of a hetero-boundary surface between a p-type GaP window layer and a p-type AlGaInP cladding layer in an epitaxial wafer for a LED of AlGaInP system shown in FIG. 1;

FIG. 3 shows a structure of another conventional epitaxial wafer for a LED of AlGaInP system;

FIG. 4 shows a structure of an epitaxial wafer for a LED of AlGaInP system according to the first preferred embodiment of the invention;

FIG. 5 explains a reason why a forward voltage of a LED according to the first preferred embodiment of the invention is reduced;

FIG. 6 shows an electrical characteristic of a LED according to the first preferred embodiment of the invention;

FIG. 7 shows a structure of an epitaxial wafer for a LED of AlGaInP system according to the second preferred embodiment of the invention;

FIG. 8 shows distribution of Zn in an epitaxial wafer shown in FIG. 7 clarified by a SIMS analysis;

FIG. 9 shows a structure of an epitaxial wafer for a LED of AlGaInP system according to a modification of the second preferred embodiment of the invention;

FIG. 10 shows distribution of Zn in an epitaxial wafer shown in FIG. 9 clarified by a SIMS analysis; and

FIG. 11 shows distribution of Zn in a conventional epitaxial wafer clarified by a SIMS analysis.

### DESCRIPTION OF THE PREFERRED EMBODIMENTS

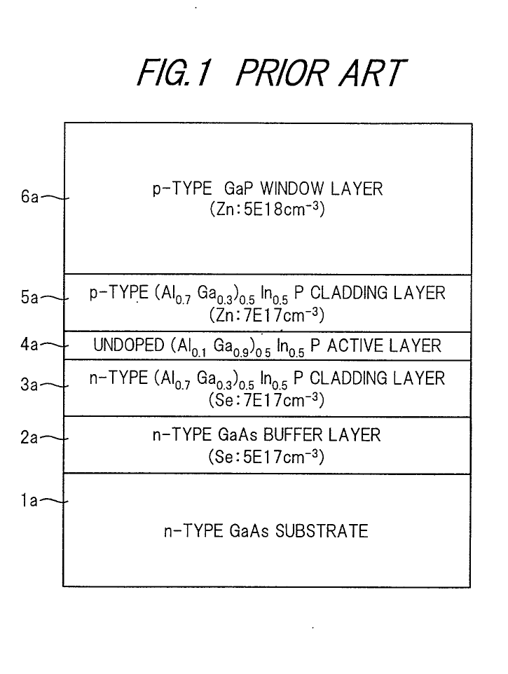

Hereafter, an epitaxial wafer for a LED of AlGaInP system and the LED according to the first preferred embodiment of the invention will be explained. Herein, structural elements used in the conventional technologies shown in FIG. 1 will be denoted by the same reference numerals as those shown in FIG. 1.

The feature of the epitaxial wafer for the LED of AlGaInP system according to the first preferred embodiment is that an insertion layer 7a having a smaller band gap energy than that of a p-type AlGaInP cladding layer 5a is formed between the p-type AlGaInP cladding layer 5a and a p-type GaP window layer 6a.

FIG. 5 explains reasons that forward voltages of the epitaxial wafer for the LED of AlGaInP system and the LED can be lowered in the first preferred embodiment of the invention.

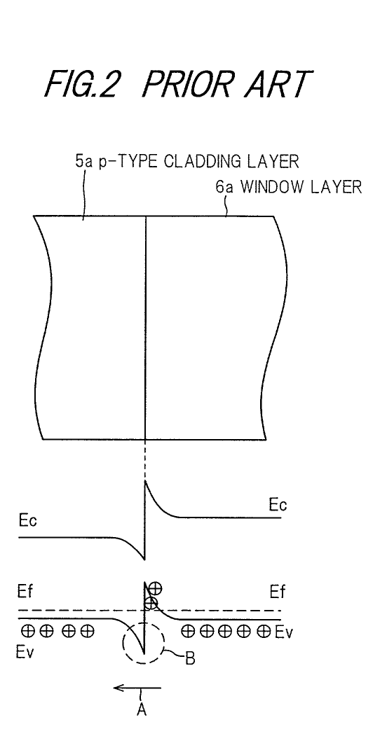

A high potential barrier is prevented from being formed on a hetero-boundary surface between the p-type (Al_{0.7}Ga_{0.3})_{0.5}In_{0.5}P cladding layer 5a and the p-type GaP window layer 6a by forming an insertion layer 7a between the p-type (Al_{0.7}Ga_{0.3})_{0.5}In_{0.5}P cladding layer 5a and the p-type GaP window layer 6a. The potential barrier shown in a broken line circle C in FIG. 5 is lower than that shown in a broken line circle B in FIG. 2. A forward voltage of the LED can be lowered by fabricating the LED using the epitaxial wafer for the LED of AlGaInP system according to the invention.

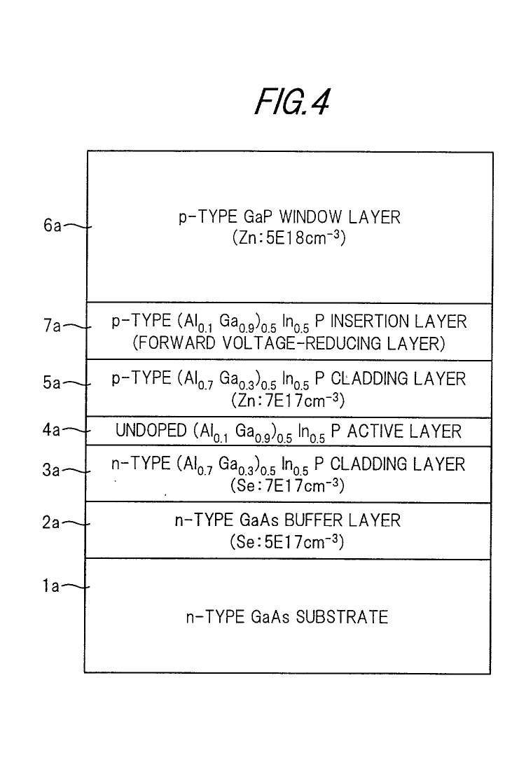

FIG. 4 shows a structure of an epitaxial wafer for a LED of AlGaInP system according to the first preferred embodiment of the invention. The first preferred embodiment of the invention will be explained for a case that the epitaxial wafer is designed for the LED emitting a red light having a wavelength of 625 nm.

The epitaxial wafer for the LED of AlGaInP system shown in FIG. 4 is fabricated as follows.

First, a n-type (Se-doped) GaAs buffer layer 2a, a n-type (Se-doped) (Al_{0.7}Ga_{0.3})_{0.5}In_{0.5}P cladding layer 3a, an undoped (Al_{0.1}Ga_{0.9})_{0.5}In_{0.5}P active layer 4a, and a p-type (Zn-doped) (Al_{0.7}GaO₃)_{0.5}In_{0.5}P cladding layer 5a are successively grown on a n-type GaAs substrate la by the MOVPE method.

Then, a 100 nm thick p-type (Al_{0.1}Ga_{0.9})_{0.5}In_{0.5}P layer 7a (a forward voltage-reducing layer, hereinafter) serving as an insertion layer (a principal structural element of the invention) is grown on the p-type cladding layer 5a by the MOVPE method, and a 10 μm thick GaP window layer is grown.

All the epitaxial layers 2a to 7a are grown in condition that a growth temperature is 700° C., a growth pressure is 50 Torr, a growth rate of all the epitaxial layers is 0.3 to 3.0 nm/s, and a V/III ratio is 100 to 600. Thereafter, the epitaxial wafer is processed to form a LED.

A size of the LED chip is 300 μm×300 μm, a n-type electrode is formed over a whole area of a bottom surface of the LED chip, and a p-type circular electrode having a diameter of 150 μm is formed on a top surface of the LED chip. Then, Au/Ge, Ni and Au layers having thicknesses of 60 nm, 10 nm, and 500 nm are successively evaporated on the n-type electrode. Similarly, Au/Zn, Ni and Au layers having thicknesses of 60 nm, 10 nm, and 1000 nm are successively evaporated on the p-type electrode. Moreover, the chip is provided with stems and resin-sealed. A light-emitting characteristic and a voltage against a current characteristic of the LED thus obtained are surveyed.

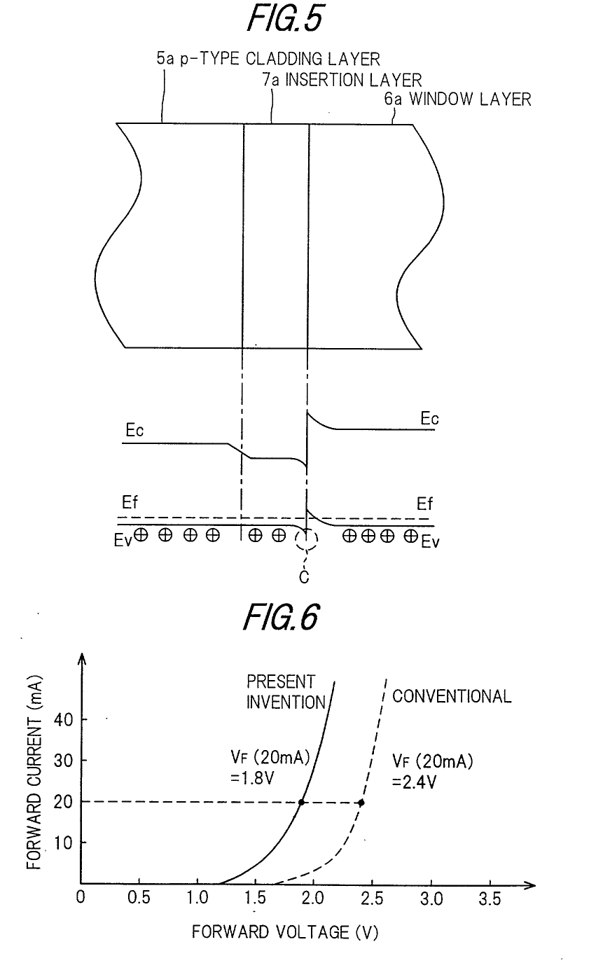

FIG. 6 shows the electrical characteristic of the LED according to the invention, wherein the abscissa shows the forward voltage and the ordinate shows the forward current.

In FIG. 6, the solid line shows the electrical characteristic of the LED according to the first preferred embodiment of the invention which comprises the (Al_{0.1}Ga_{0.9})_{0.5}In_{0.5}P active layer and the forward voltage-reducing layer 7a, and the broken line shows that of the conventional LED.

Although the forward voltage of the conventional LED is 2.4V, that of the LED fabricated from the epitaxial wafer for the LED of AlGaInP system according to the first preferred embodiment of the invention is 1.8V, and a noticeable improvement can be achieved by the invention.

The lowest value of the forward voltage of the LED is determined by the band gap energy of the active layer 4a. The forward voltage of 1.8V is closed to the lowest value achieved by the band gap energy of the active layer 4a of the epitaxial wafer for the LED of AlGaInP system according to the first preferred embodiment of the invention, which is nearly equal to the forward voltage in case that a AlGaAs window layer is used. A potential barrier is sufficiently prevented from being formed on the hetero-boundary surface between the p-type GaP window layer 6a and the p-type cladding layer 5a by providing the forward voltage-reducing layer 7a. Moreover, the brightness of the light emitted from the LED according to the first preferred embodiment of the invention does not become lower than that of the conventional LED by providing the forward voltage-reducing layer 7a.

Although an insertion layer 7a having a smaller band gap energy than that of the p-type cladding layer 5a may be inserted between the p-type cladding layer 5a and the p-type GaP window layer 6a in order to reduce the potential barrier caused by a discontinuity in the energy bands therebetween, if the forward voltage-reducing layer 7a having a smaller band gap energy than that of the active layer 4a is inserted, the light emitted from the active layer 4a is absorbed by the forward voltage-reducing layer 7a, and the light-transmitting efficiency of the LED becomes extremely low. Accordingly, it is desirable that the band gap energy of the forward voltage-reducing layer 7a is smaller than that of the p-type cladding layer 5a and larger than that of the active layer 4a.

Moreover, it is desirable that the conductivity type of the forward voltage-reducing layer 7a is p-type similarly to the p-type cladding layer 5a and the p-type GaP window layer, and concentration of carriers thereof is more than 5×10¹⁷ cm⁻³and less than 5×10¹⁸ cm⁻³. If concentration of carriers in the forward voltage-reducing layer 7a is less than 5×10¹⁷ cm⁻³, a resistivity of the forward voltage-reducing layer 7a becomes high, so that the forward voltage is heightened. If concentration of carriers in the forward voltage-reducing layer 7a is more than 5×10¹⁸ cm⁻³, defects in the crystal increase and the light-emitting efficiency is lowered.

It is desirable that the forward voltage-reducing layer 7a is lattice-matched with the p-type cladding layer 5a serving as an underlying layer thereof. If the former is not lattice-matched with the latter, the defects are caused in the epitaxial layer, so that there arise problems that the light-emitting efficiency is lowered and the surface of the p-type GaP window layer is blurred.

Although the explanations are given on the epitaxial wafer having the n-type substrate and the LED fabricated from the same in the above descriptions, the conductivity type of the substrate is never restricted to the n-type, and the same effect can be achieved in an epitaxial wafer having a p-type substrate and a LED fabricated from the same.

In a word, according to the invention, the excellent results mentioned as the follows can be achieved.

The epitaxial wafer for the LED of AlGaInP system and the LED fabricated from the same in which the forward voltage is low can be provided.

Hereafter, the second preferred embodiment of the invention will be explained in detail referring to the appended drawings.

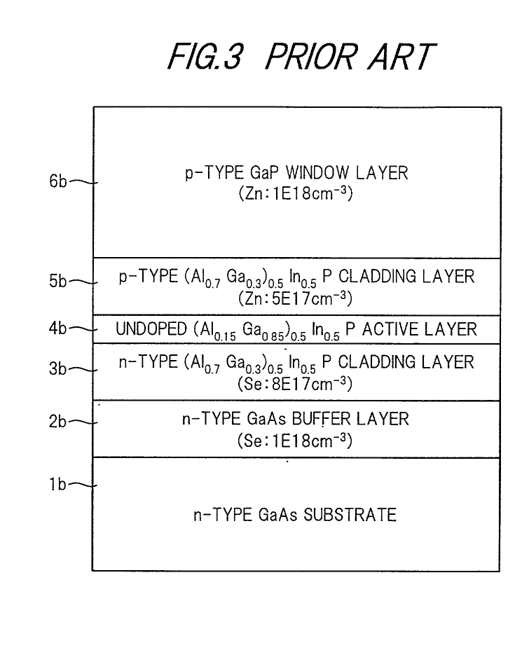

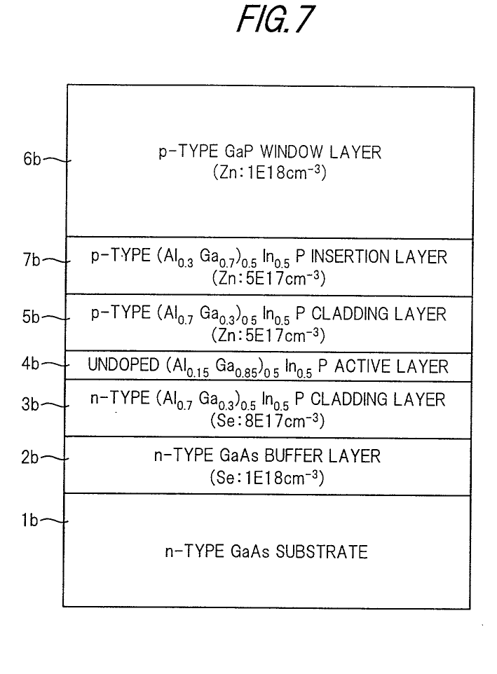

FIG. 7 shows the second preferred embodiment of an epitaxial wafer for an LED according to the invention. Herein, structural elements having the same functions as those shown in FIG. 3 are denoted by the same reference numerals.

The epitaxial wafer for the LED is fabricated by successively growing a n-type GaAs buffer layer 2b, a n-type (Al_{0.7}Ga_{0.3)}_{0.5}In_{0.5}P cladding layer 3b, an undoped (Al_{0.5}Ga_{0.85})_{0.5}In_{0.5}P active layer 4b, a p-type (Al_{0.7}Ga_{0.3})_{0.5}In_{0.5}P cladding layer 5b, a p-type (Al_{0.3}Ga_{0.7})_{0.5}In_{0.5}P insertion layer 7b, and a p-type GaP window layer 6b on a n-type GaAs substrate 1b.

It is desirable that the insertion layer 7b is formed of material of AlGaInP system similarly to the p-type cladding layer 5b, and a composition ratio of Al in the insertion layer 7b should be lower than that in the p-type cladding layer 5b and higher than that in the active layer 4b. The reason that the aforementioned structure is adopted is that unwanted pollution can be avoided, and crystal can be grown easily. However, the insertion layer 7b is not necessarily formed of material of AlGaInP system, and the diffusion of Zn can be suppressed by inserting an AlGaAs layer or a GaAs layer containing no Al.

The reason that the lattice constant of the insertion layer 7b is matched with that of the underlying p-type cladding layer 5b is that defects in the epitaxial layers can be prevented from being caused.

Moreover, the reason that a composition ratio of Al in the insertion layer 7b is higher than that in the active layer 4b is that a light emitted from the active layer 4b can transmit through the insertion layer 7b.

The reason that concentration of carriers in the insertion layer 7b is made 2×10¹⁷cm⁻³to 5×10¹⁸ cm⁻³is that, if concentration of carrier is lower than 2×10¹⁷ cm⁻³ the resistivity of the insertion layer 7b becomes high and the driving voltage of the LED becomes too high, and if concentration of carriers is higher than 5×10¹⁸ cm⁻³ the crystallization of the insertion layer deteriorates and the light-emitting power of the LED is lowered, hence the practical LED cannot be provided in both the cases.

Although it is desirable that the band gap energy of the insertion layer 7b is larger than that of the active layer 4b so that the emitted light is not absorbed by the insertion layer 7b, if the insertion layer 7b is so thin that the absorption of the emitted light is negligible, even the insertion layer 25 7b having a smaller band gap energy than that of the active layer 4b can achieve a satisfactory result, so that the insertion layer 7b having the smaller band gap energy is not necessarily rejected.

Since the optimum value of the thickness of the insertion layer 7b exists in accordance with a composition ratio of Al in the insertion layer 7b, the kind of the p-type cladding layer 5b, amount of doping of Zn in the window layer 6b and a thermal hysteresis in the period of the epitaxial growth, the thickness of the insertion layer 7b is not necessarily limited.

In order to prevent the diffusion of Zn from being extended to the active layer 4b, the plural insertion layers 7b may be inserted into the p-type cladding layer 5b.

[Embodiment 1b]

An epitaxial wafer for a LED of AlGaInP system having a structure shown in FIG. 7 which emits a red light having a wavelength of 620 nm is fabricated as the second preferred embodiment of the invention.

The structure of the epitaxial wafer and a method for the epitaxial growth are the same as those of an example for comparison mentioned afterward, and a 0.1 μm thick 5×10¹⁷ cm⁻³ Zn doped p-type (Al_{0.3}Ga_{0.7})_{0.5}In_{0.5}P insertion layer is inserted between the p-type cladding layer 5b and the window layer 6b.

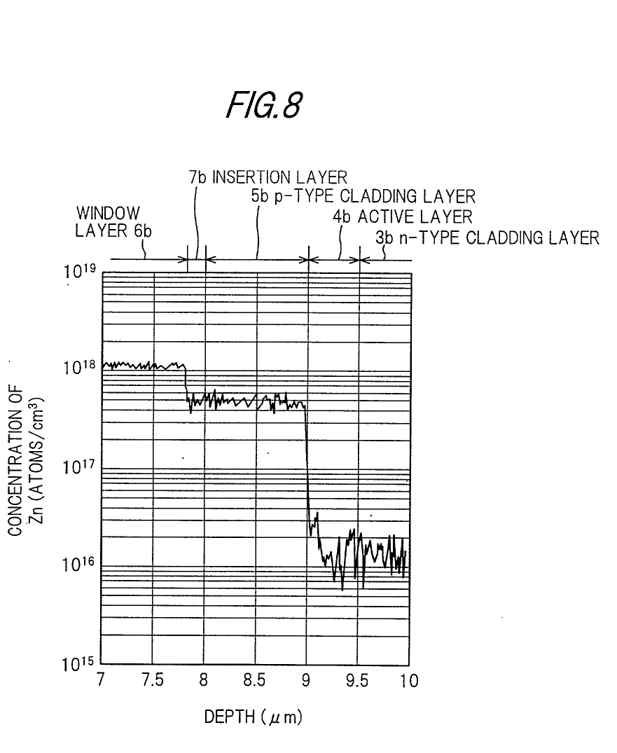

FIG. 8 shows the distribution of concentration of Zn in the epitaxial wafer fabricated as the second preferred embodiment of the invention, which is analyzed by a SIMS. The abscissa means the depth, and the ordinate (a log scale) means concentration of Zn.

As seen from FIG. 8, the distribution of Zn is nearly the same as the expectations of the inventions, and the abnormal diffusion of Zn which occurred in the conventional LED cannot be observed.

Thereafter, the epitaxial wafer is processed to fabricate a LED in a usual way, and the light emitting characteristic of the LED is surveyed. The light emitting power is 1.1 mW and a forward voltage in case that a supply current is 20 mA is 1.9V.

[Embodiment 2b]

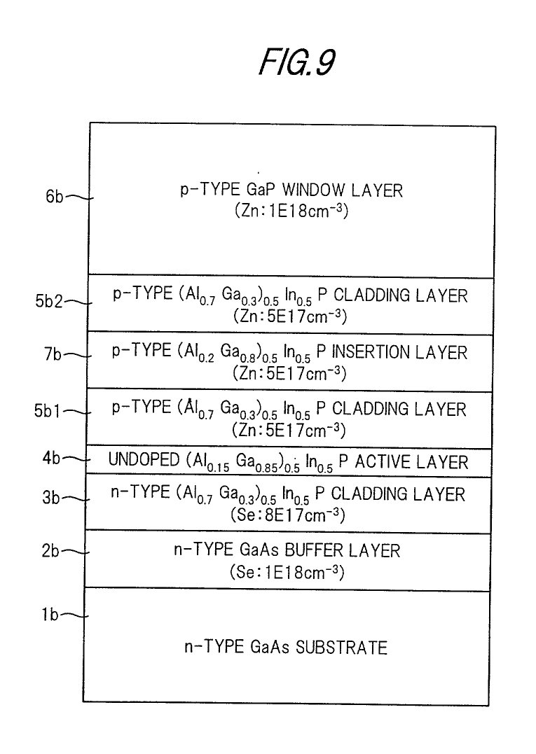

FIG. 9 shows a structure of an epitaxial wafer of AlGaInP system for a LED according to a modification of the second preferred embodiment of the invention.

FIG. 9 shows an epitaxial wafer to be used for the LED emitting a red light having a wavelength of about 620 nm.

Although the structure and the method for the epitaxial growth of the embodiment 2b are basically the same as those of the aforementioned embodiment 1b, a 0.1 μm thick 5×10¹⁷ cm⁻³ Zn doped p-type (AlO₂Ga_{0.8})_{0.5}In_{0.5}P layer is inserted between the p-type cladding layers 5b1 and 5b2 as an insertion layer 7b.

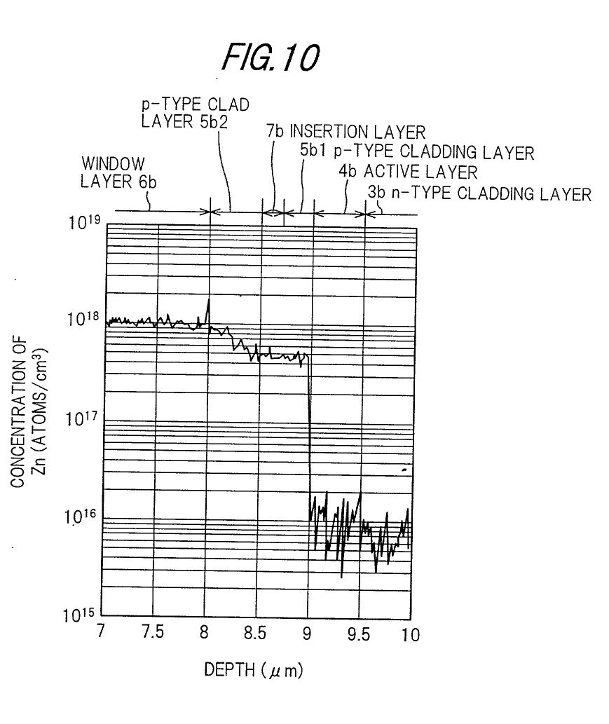

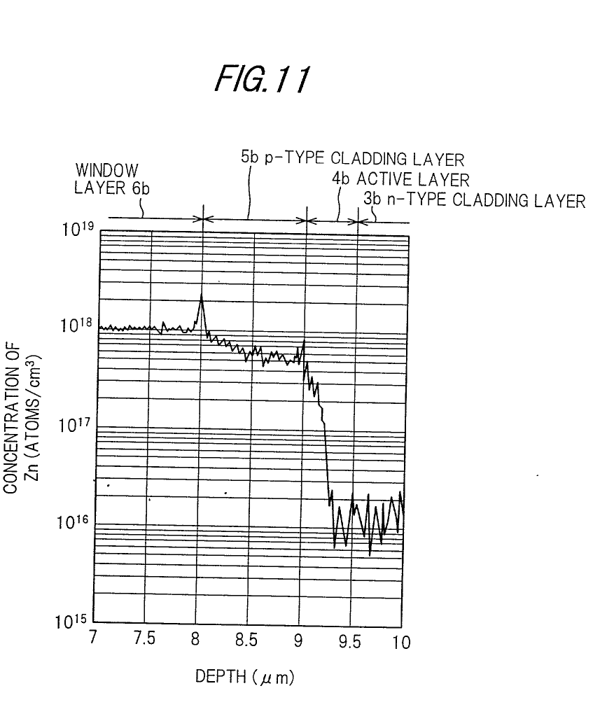

FIG. 10 shows the result of the SIMS analysis on concentration of Zn in the epitaxial wafer shown in FIG. 9, wherein the abscissa shows the depth, and the ordinate (a log scale) shows concentration of Zn.

As seen from FIG. 10, the distribution of Zn ceases at the insertion layer 7b just as the expectations of the inventors, and the diffusion of Zn cannot be observed in the active layer 4b.

Moreover, the epitaxial wafer thus obtained is processed to form a LED, and the light emitting characteristic thereof is surveyed. The light-emitting power is 1.3 mW, and the forward voltage in case that a current of 20 mA is supplied to the LED is 1.9V.

[Example for Comparison]

An epitaxial wafer for a LED emitting a red light having a wavelength of about 620 nm is fabricated on the basis of FIG. 3.

A n-type (Se-doped) GaAs buffer layer 2b, a n-type (Se-doped) cladding layer 3b, an active layer 4b, and a p-type cladding layer 5b are successively grown on a n-type GaAs substrate 1b by the MOVPE growth, and a window layer 6b having a thickness of 10 μm are further grown on the p-type clap layer 5b.

The MOVPE growth of the epitaxial layers 2b to 5b is performed at a growth temperature of 700° C. and a growth pressure of 50 Torr till the p-type cladding layer 5b is formed; and the epitaxial layers 2b, 3b, and 4b are grown at a growth rate of 0.3 to 1.0 nm/s, and at a V/III ratio of 300 to 600. The window layer 6b is grown at a V/III ratio of 100, and at a growth rate of 1 nm/s. Concentration of Zn in the p-type cladding layer 5b is 5×10¹⁷ cm⁻³, and concentration of Zn in GaP of the window layer 6b is 1×10⁸ cm³.

FIG. 11 shows the distribution of concentration of Zn in the conventional epitaxial wafer in the depth direction measured 20 by the SIMS, wherein the abscissa shows the depth, and the ordinate (a log scale) shows concentration of Zn.

It is confirmed that Zn in the window layer 6b diffuses into the n-type cladding layer 3b, the active layer 4b, and the light emitting region of the p-type cladding layer 5b in large quantities as the result of the SIMS analysis.

Moreover, the epitaxial wafer is processed to fabricate a LED. The size of a chip is 300 μm×300 μm, a n-type electrode is formed over a whole bottom surface of the chip, and a p-type circular electrode having diameter of 150 μm is formed on the top surface of the chip. The n-type electrode is formed by successively evaporating Au/Ge, Ni and Au layers having thickness of 60 nm, 10 nm and 500 nm. The p-type electrode is formed by successively evaporating Au/Zn, Ni and Au layers having thickness of 60 nm, 10 nm and 100 nm. After forming stems on this chip, a light-emitting characteristic is surveyed. The light-emitting power is 0.6 mW, and the forward voltage is 2.4V in case that a current of 20 mA is supplied to the LED.

As mentioned in the above, according to the invention, the LED having a high light-emitting power and high reliability can be obtained by a simple structure.

Since the conventional wafer is poor in reproducibility of diffusion of Zn, the fluctuation of distribution of concentration of Zn is noticeable in the individual wafers and between lots of the wafers, which is a cause of deterioration of uniformity and reproducibility of the products. However, according to the invention, since the diffusion of Zn can be suppressed, the aforementioned problems can be solved.

Since concentration of Zn distributes just as the inventors have expected, a layer having carriers of high concentration can be formed between the p-type cladding layer and the window layer, and the LED having a low forward voltage can be obtained with high reproducibility.

In a word, according to the invention, the excellent results mentioned as follows can be achieved.

The epitaxial wafer for the LED of AlGaInP system and the LED fabricated from the same in which the forward voltage is low can be provided.

Although the invention has been described with respect to specific embodiment for complete and clear disclosure, the appended claims are not to be thus limited but are to be construed as embodying all modification and alternative constructions that maybe occurred to one skilled in the art which fairly fall within the basic teaching herein set forth.

What is claimed is:

1. A LED of AlGaInP system, comprising:
a substrate having conductivity,
a n-type cladding layer formed of compound semiconductor of AlGaInP system,
an active layer formed of compound semiconductor of AlGaInP system having a smaller band gap energy than that of said n-type cladding layer,
a p-type cladding layer formed of compound semiconductor of AlGaInP system having a larger band gap energy than that of said active layer,
a p-type window layer formed of GaP,
electrodes formed on predetermined portions of said window layer and said substrate, and
an insertion layer which is inserted between said p-type cladding layer and said p-type window layer and has a smaller band gap energy than that of said p-type cladding layer.

2. A LED of AlGaInP system according to claim 1, wherein:
said band gap energy of said insertion layer is larger than that of said active layer.

3. A LED of AlGaInP system according to claim 1, wherein:
a conductivity type of said insertion layer is p-type.

4. A LED of AlGaInP system according to claim 3, wherein:
concentration of carriers in said p-type insertion layer is 5×10¹⁷ cm⁻³ to 5×10¹⁸ cm⁻³.

5. A LED of AlGaInP system according to claim 1, wherein:
said insertion layer is lattice-matched with said p-type cladding layer.

6. A LED of AlGaInP system according to claim 1, wherein:
said insertion layer is formed of AlGaInP, GaInP, AlInP, GaAs, AlGaAs, GaAsP or InGaAsP, which has such a composition that said band gap energy thereof is smaller than that of said p-type cladding layer.

7. A LED of AlGaInP system comprising:
a substrate having conductivity,
a n-type cladding layer formed of compound semiconductor of AlGaInP system,
an active layer formed of compound semiconductor of AlGaInP system having a smaller band gap energy than that of said n-type cladding layer,
a p-type cladding layer formed of compound semiconductor of AlGaInP system having a larger band gap energy than that of said active layer,
a window layer formed of GaₓIn₁₋ₓP(0<x≦1) Al_{y}In_{1-y}P(0<y≦1) or Al_{z}Ga_{1-z}P(0<z≦1)
electrodes formed on predetermined portions of said window layer and said substrate, and
an insertion layer which is inserted between said p-type cladding layer and said window layer and has a smaller band gap energy than that of said p-type cladding layer.

8. An epitaxial wafer for a LED of AlGaInP system, comprising:
a substrate having conductivity,
a n-type cladding layer formed of compound semiconductor of AlGaInP system,
an active layer formed of compound semiconductor of AlGaInP system having a smaller band gap energy than that of said n-type cladding layer,
a p-type cladding layer formed of compound semiconductor of AlGaInP system having a larger band gap energy than that of said active layer,
a p-type window layer formed of GaP, and
an insertion layer which is inserted between said p-type cladding layer and said p-type window layer and has a smaller band gap energy than that of said p-type cladding layer.

9. An epitaxial wafer for a LED of AlGaInP system according to claim 8, wherein:
said band gap energy of said insertion layer is larger than that of said active layer.

10. An epitaxial wafer for a LED of AlGaInP system according to claim 8, wherein:
a conductivity type of said insertion layer is p-type.

11. An epitaxial wafer for a LED of AlGaInP system according to claim 10, wherein:
concentration of carriers in said insertion layer is 5×10¹⁷ cm⁻³ to 5×10¹⁸ cm⁻³.

12. An epitaxial wafer for a LED of AlGaInP system according to claim 8, wherein:
said insertion layer is lattice-matched with said p-type cladding layer.

13. An epitaxial wafer for a LED of AlGaInP system according to claim 8, wherein:
said insertion layer is formed of compound semiconductor of AlGaInP, GaInP, AlInP, GaAs, AlGaAs, GaAsP or InGaAs, which has such a composition that said band gap energy thereof is smaller than that of said p-type cladding layer.

14. An epitaxial wafer for a LED of AlGaInP system comprising:
a substrate having conductivity,
a n-type cladding layer formed of compound semiconductor of AlGaInP system,
an active layer formed of compound semiconductor of AlGaInP system having a smaller band gap energy than that of said n-type cladding layer,
a p-type cladding layer formed of compound semiconductor of AlGaInP system having a larger band gap energy than that of said active layer,
a window layer formed of GaₓIn₁₋ₓP(0<x≦1), Al_{y}In_{1-y}P(0<y≦1) or Al_{z}Ga_{1-z}P(0<z≦1), and
an insertion layer which is inserted between said p-type cladding layer and said window layer and has a smaller band gap energy than that of said p-type cladding layer.

15. A LED of AlGaInP system, comprising:
a substrate having n-type conductivity,
a n-type cladding layer formed of compound semiconductor of AlGaInP system,
an active layer formed of compound semiconductor of AlGaInP system having a smaller band gap energy than that of said n-type cladding layer,
a p-type cladding layer formed of compound semiconductor of AlGaInP system having a larger band gap energy than that of said active layer,
a p-type window layer, and
an insertion layer formed of compound semiconductor of AlGaInP system which is inserted into said p-type cladding layer or between said p-type cladding layer and said p-type window layer,
wherein said insertion layer is lattice-matched with said p-type cladding layer, and a composition ratio of Al in said insertion layer is lower than that in said p-type cladding layer and higher than that in said active layer.

16. A LED of AlGaInP system according to claim 15, wherein:
said p-type window layer is formed of GaP.

17. A LED of AlGaInP system according to claim 15, wherein:
said p-type cladding layer and said p-type window layer are doped with Zn.

18. A LED of AlGaInP system according to claim 15, wherein:
concentration of carriers in said insertion layer is 2×10¹⁷ cm⁻³ to 5×10¹⁸ cm⁻³.

19. An epitaxial wafer for a LED of AlGaInP system, comprising:
a substrate having n-type conductivity,
a n-type cladding layer formed of compound semiconductor of AlGaInP system,
an active layer formed of compound semiconductor of AlGaInP system having a smaller band gap energy than that of said n-type cladding layer,
a p-type cladding layer formed of compound semiconductor of AlGaInP system having a larger band gap energy than that of said active layer,
a p-type window layer, and
an insertion layer formed of compound semiconductor of AlGaInP system which is inserted into said p-type cladding layer or between said p-type cladding layer and said p-type window layer,
wherein said insertion layer is lattice-matched with said p-type cladding layer, and a composition ratio of Al in said insertion layer is lower than that in said p-type cladding layer and higher than that in said active layer.

20. An epitaxial wafer for a LED of AlGaInP system according to claim 19, wherein:
said p-type window layer is formed of GaP.

21. An epitaxial wafer for a LED of AlGaInP system according to claim 19, wherein: said p-type cladding layer and said p-type window layer are doped with Zn.

22. An epitaxial wafer for a LED of AlGaInP system according to claim 19, wherein: concentration of carriers in said insertion layer is 2×10¹⁷ cm⁻³ to 5×10¹⁸ cm⁻³.
